(19) United States
(12) Patent Application Publication
(10) Pub. No.: US 2009/0242867 A1
(43) Pub. Date: Oct. 1, 2009

(54) PHASE CHANGE MEMORY DEVICE HAVING PROTECTIVE LAYER FOR PROTECTING PHASE CHANGE MATERIAL AND METHOD FOR MANUFACTURING THE SAME

(75) Inventor: Dae Ho Rho, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR, INC., Ichon (KR)

(21) Appl. No.: 12/246,653

(22) Filed: Oct. 7, 2008

(30) Foreign Application Priority Data
Mar. 27, 2008 (KR) 10-2008-0028301

(51) Int. Cl. H01L 45/00

(52) U.S. Cl. 257/4; 438/102; 257/E45.002

(57) ABSTRACT

A phase change memory device includes a semiconductor substrate, a plurality of bottom electrodes formed on the substrate, a plurality of phase change structures formed on the semiconductor substrate, each respectively contacting one of the bottom electrodes, and each having a phase change material layer and a top electrode stacked one upon the other, and a protective layer formed to a substantially uniform thickness on surfaces of the plurality of phase change structures and the semiconductor substrate, wherein the protective layer contains diffusion barrier ions.

### CROSS-REFERENCES TO RELATED APPLICATION

The present application claims priority under 35 U.S.C. §119(a) to Korean Patent Application No. 10-2008-0028301, filed in Korea on Mar. 27, 2008, which is incorporated by reference in its entirety as if set forth in full.

### BACKGROUND

1. Technical Field

The embodiments described herein relate to a phase change memory device, and more particularly, to a phase change memory device which has a protective layer for protecting a phase change material and a method for manufacturing the same.

2. Related Art

Generally, memory devices are commonly divided into a volatile RAM (random access memory), which loses information input into the device when power is interrupted, and a non-volatile ROM (read-only memory), which can continuously hold information even when power is interrupted. Currently, a DRAM (dynamic RAM) and an SRAM (static RAM) are commonly used as the RAM, and a flash memory device is commonly used as the ROM.

The DRAM has advantages in that power consumption is reduced and optional access is possible, and has disadvantages in that it is volatile and requires high charge storage capacity, which requires an increase in the capacity of capacitors included in the device. For example, using the SRAM as a cache memory has advantages in that optional access is possible and it has a high operation speed, and has disadvantages in that it is volatile and has a substantial size so that the manufacturing cost is increased. Further, in the flash memory device, while it is non-volatile, a high operation voltage is required when compared to a power source voltage due to the stacked gate structure of the device. Accordingly, since a separate booster circuit, which has a relatively large size, is needed to supply a voltage required for write and delete operations in the flash memory and the RAM device, it is difficult to accomplish a high level of integration and a high operation speed.

In order to overcome the disadvantages of these memory devices, other RAMs have been developed, such as a ferroelectric random access memory (FRAM), a magnetic random access memory (MRAM), and a phase change random access memory (PRAM).

Among these RAMs, the PRAM is a memory device which writes and reads information by the phase change of a phase change material having high resistance in an amorphous phase and low resistance in a crystalline phase. Thus, the PRAM provides advantages in that it has a high operation speed and a high integration level when compared to the flash memory device.

The phase change material is a material in which phase changes between a crystalline phase and an amorphous phase are dependent upon a temperature of the material. In the crystalline phase, the phase change material has low resistance and regular atomic arrangement when compared to the amorphous phase. A typical example of the phase change material is Chalcogenide, which is a compound made of GST, that is, germanium (Ge), antimony (Sb), and tellurium (Te). The phase change material changes its phase state depending upon its temperature, whereby the memory operates.

However, as the memory operates repeatedly, heat is generated by the repeated expansion and contraction of the phase change material. Accordingly, the phase change material is likely to delaminate from bottom electrode contacts (BECs). Also, since the phase change material is formed using the composite compound described above, the constituents of the phase change material are likely to diffuse to the outside during fabrication processing.

In order to prevent or avoid the delamination of the phase change material from the bottom electrode contacts and to prevent the diffusion of the constituents of the phase change material after forming a phase change material layer and top electrodes, a protective layer is formed as an encapsulator to prevent degradation of the properties of the phase change material during the phase changing. For example, a silicon oxide layer and a silicon nitride layer are used as the protective layer.

In the case that the protective layer is formed of the silicon oxide layer, it is difficult to prevent the diffusion of the constituents of the phase change material into the protective layer, and the silicon oxide layer may be recombined with the diffusing constituents to create an interface having abnormal composition. This abnormal composition interface can adversely influence the operation of the phase change material layer and can actually facilitate the diffusion of the constituents of the phase change material layer into the protective layer to further degrade the properties of the phase change material.

Meanwhile, in the case that the protective layer is formed of the silicon nitride layer, since the silicon nitride layer is formed at a substantially high temperature over 400° C., a thermal burden can be imposed on the phase change material layer.

In addition, because the silicon nitride layer has poor step coverage characteristics, it cannot be deposited to a substantially uniform thickness on the sidewalls of the phase change material layer. As a consequence, the silicon nitride layer may be formed in the shape of relatively thick overhangs on the upper edges of the phase change material layer. When forming a buried layer to fill spaces between adjacent portions of the phase change material layer, it is difficult to fill the spaces due to the presence of the overhangs.

Therefore, it is necessary to provide a protective layer having excellent diffusion barrier characteristics formed to a substantially uniform thickness that can prevent delamination between bottom electrode contacts and a phase change material layer.

### SUMMARY

A phase change memory device having protective layer for protecting phase change material and method for manufacturing the same are described herein.

In one aspect, a phase change memory device includes a semiconductor substrate, a plurality of bottom electrodes formed on the substrate, a plurality of phase change structures formed on the semiconductor substrate, each respectively contacting one of the bottom electrodes, and each having a phase change material layer and a top electrode stacked one upon the other, and a protective layer formed to a substantially uniform thickness on surfaces of the plurality of phase change structures and the semiconductor substrate, wherein the protective layer contains diffusion barrier ions. In another aspect, a method for manufacturing a phase change memory device includes preparing a semiconductor substrate having a plurality of bottom electrodes, forming a plurality of phase change structures on the semiconductor substrate, each contacting one of the bottom electrodes, and each having a phase change material layer and a top electrode, forming a protective layer to a substantially uniform thickness on surfaces of the phase change structures and the semiconductor substrate, and implanting diffusion barrier ions into the protective layer.

These and other features, aspects, and embodiments are described below.

### BRIEF DESCRIPTION OF THE DRAWINGS

Features, aspects, and embodiments are described in conjunction with the attached drawings, in which:

FIGS. 1-5 are cross sectional views of an exemplary method for manufacturing a phase change memory device according to one embodiment.

### DETAILED DESCRIPTION

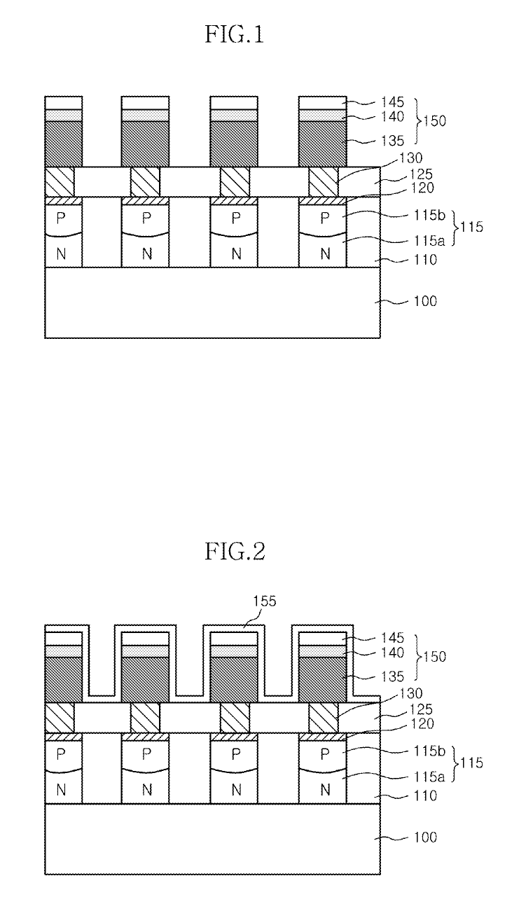

FIGS. 1-5 are cross sectional views of an exemplary method for manufacturing a phase change memory device according to one embodiment. Referring to FIG. 1, a first interlayer dielectric 110 having switching elements can be formed on a semiconductor substrate 100. The semiconductor substrate 100 can be a silicon substrate in which active regions (not shown) and isolation regions (not shown) are formed. The switching elements in the first interlayer dielectric 100 can be, for example, PN diodes 115 each comprising an N-type SEG (selective epitaxial growth) layer 115a and a P-type SEG layer 115b. While not shown in the drawing, the PN diodes 115 can be electrically contacted with the active regions.

A second interlayer dielectric 125 having bottom electrode contacts 130 (or bottom electrodes) can be formed on the first interlayer dielectric 110 having the PN diodes 115. Each of the bottom electrode contacts 130 can be electrically connected with a corresponding one of the PN diodes 115. An ohmic contact layer 120 can be interposed between each of the bottom electrode contacts 130 and each of the corresponding PN diodes 115.

A phase change material layer 135, a conductive layer 140 (for functioning as top electrodes), and an anti-reflection layer 145 can then be sequentially formed on the second interlayer dielectric 125 by deposition, for example. Then, phase change structures 150, which respectively correspond to the bottom electrode contacts 130, can be formed by etching predetermined portions of the anti-reflection layer 145, the conductive layer 140, and the phase change material layer 135.

Referring to FIG. 2, a first protective layer 155 can be formed on top and side surfaces of the phase change structures 150 and the second interlayer dielectric 125 between adjacent ones of the phase change structures 150. The first protective layer 155 can comprise an insulation layer having excellent step coverage characteristics. For example, the insulation layer can contain constituents of a silicon oxide layer. The thickness of the first protective layer 155 can be changed depending upon the gaps between and the height of the phase change structures 150. The thickness of the first protective layer 155 can, for example, be 10 Å to 1,000 Å, and preferably, 10 Å to 250 Å. In addition, the first protective layer 155 can be formed at a temperature ranging from about room temperature to a temperature at about which the diffusion of the phase change material layer 135 does not occur, for example, between 20° C. and 400° C. The first protective layer 155 can be formed through a liquid phase coating process in order to prevent any thermal diffusion of the constituents from the phase change material layer 135 into the first protective layer 155. Additionally, the liquid phase coating process is advantageous in that step coverage characteristics of the first protective layer 155 can be improved.

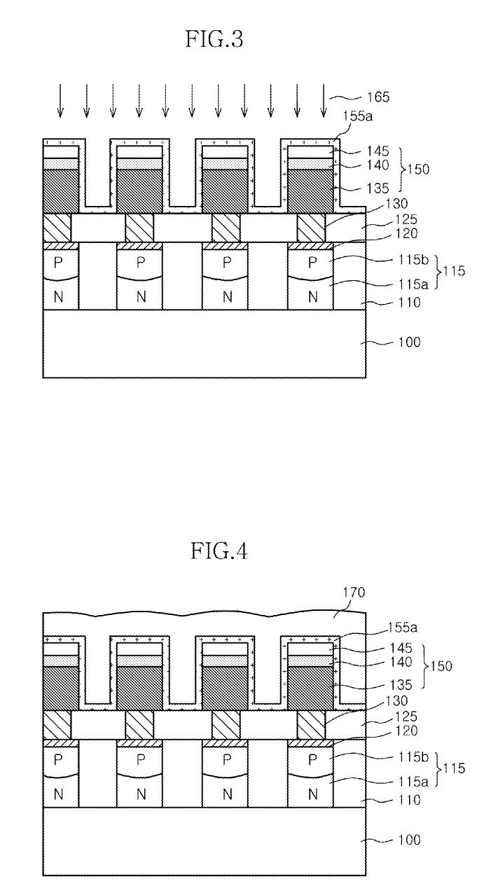

Referring to FIG. 3, diffusion barrier processing 165 can be performed for the first protective layer 155. In certain embodiment, the diffusion barrier processing 165 can implant diffusion barrier ions into the first protective layer 155. For example, the diffusion barrier ions can include ions for preventing back-diffusion and ions that react with the constituents diffusing from the phase change material layer 135 to prevent formation of a conductive layer. As an example, nitrogen (N) or phosphorus (P) ions can be used. The diffusion barrier ions can be implanted into the first protective layer 155 and generate bonds (i.e., dangling bonds) that do not combine with any atoms in the first protective layer 155. The dangling bonds capture diffusing constituents of the phase change material layer 135 when they diffuse out from the phase change material layer 135. The diffusion barrier ions can be implanted by an amount capable of completely saturating the first protective layer 155. The reference numeral 155a designates the first protective layer into which the diffusion barrier ions are implanted.

Referring to FIG. 4, a second protective layer 170 can be formed on the first protective layer 155a such that the spaces between adjacent phase change structures 150 are filled. For example, the second protective layer 170 can be formed through a liquid phase coating process to provide excellent gap-fill characteristics between the adjacent phase change structures 150. A planarized layer having insulating characteristics can be used as the second protective layer 170.

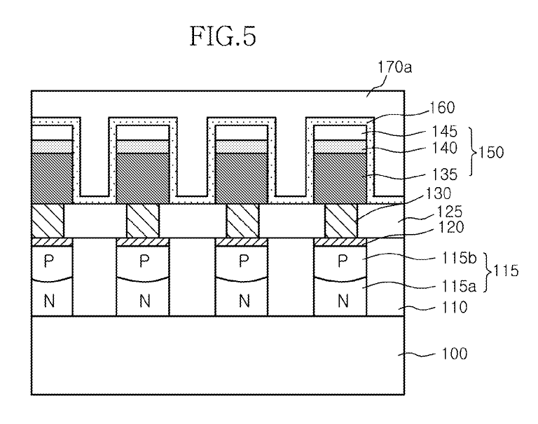

Next, as shown in FIG. 5, the second protective layer 170 can be densified. Since the second protective layer 170 is formed using the liquid phase coating process and low temperature deposition, the density of the second protective layer 170 is likely to be relatively low when compared to a similar material layer deposited at a relatively high temperature. Accordingly, by annealing the second protective layer 170, the density of the second protective layer 170 can be substantially increased. Here, while the annealing temperature can be changed depending upon the thickness of the second protective layer 170 and the type(s) of material(s) used, the annealing can be conducted at a temperature of 100° C. to 400° C. for 10 to 40 minutes in consideration of the diffusion of the constituents of the phase change material layer 135 placed thereunder as well as a thermal burden to be imposed on the phase change material layer 135 during the annealing process. By the annealing process, the diffusion barrier ions implanted into the first protective layer 155a are activated. The reference numeral 160 designates the first protective layer having the activated diffusion barrier ions.

Thereafter, the second protective layer 170 can be planarized. The reference numeral 170a designates the planarized second protective layer.

Although the present exemplary embodiment is described to include the protective layer comprising the first protective layer implanted with the diffusion barrier ions and the second protective layer having excellent gap fill characteristics, the first and second protective layers can be repeatedly stacked to constitute a composite protective layer.

As is apparent from the above description, by implanting diffusion barrier ions into a relatively low temperature insulation layer having excellent step coverage characteristics, the resultant structure can be used as a protective layer. Accordingly, constituents diffusing from out of a phase change material layer can be easily captured, and formation of voids between adjacent phase change material structures can be prevented. In addition, since the protective layer is deposited at a relatively low temperature, a thermal burden imposed on a phase change material layer can be reduced. Furthermore, since the protective layer comprises the constituents of a silicon oxide layer, adhesion characteristics between adjacent insulation and protection layers are improved. Moreover, since an additional densified and planarized protective layer is formed, delamination between bottom electrode contacts and the phase change material layer can be prevented.

While certain embodiments have been described above, it will be understood that the embodiments described are by way of example only. Accordingly, the device and method described herein should not be limited based on the described embodiments. Rather, the devices and methods described herein should only be limited in light of the claims that follow when taken in conjunction with the above description and accompanying drawings.

What is claimed is:

1. A phase change memory device, comprising:
a semiconductor substrate;
a plurality of bottom electrodes formed on the substrate;
a plurality of phase change structures formed on the semiconductor substrate, each respectively contacting one of the bottom electrodes, and each having a phase change material layer and a top electrode stacked one upon the other; and
a protective layer formed to a substantially uniform thickness on surfaces of the plurality of phase change structures and the semiconductor substrate,
wherein the protective layer contains diffusion barrier ions.

2. The phase change memory device according to claim 1, wherein the protective layer contains constituents of a silicon oxide layer.

3. The phase change memory device according to claim 1, wherein the diffusion barrier ions comprise nitrogen ions or phosphorus ions.

4. The phase change memory device according to claim 1, further comprising a gap-fill protective layer formed on the protective layer filling spaces between each of the phase change structures.

5. The phase change memory device according to claim 4, wherein the gap-fill protective layer has a planarized surface.

6. A method for manufacturing a phase change memory device, comprising the steps of:
preparing a semiconductor substrate having a plurality of bottom electrodes;
forming a plurality of phase change structures on the semiconductor substrate, each contacting one of the bottom electrodes, and each having a phase change material layer and a top electrode;
forming a protective layer to a substantially uniform thickness on surfaces of the phase change structures and the semiconductor substrate; and
implanting diffusion barrier ions into the protective layer.

7. The method according to claim 6, wherein the protective layer is formed at a temperature between 20° C. and 400° C.

8. The method according to claim 6, wherein the protective layer is formed through a liquid phase coating process.

9. The method according to claim 6, wherein the protective layer comprises a silicon oxide layer.

10. The method according to claim 9, wherein the diffusion barrier ions comprise nitrogen ions or phosphorus ions.

11. The method according to claim 6, wherein, after implanting the diffusion barrier ions, the method further comprises the step of:
forming an additional gap-fill protective layer on the protective layer to fill spaces between each of the phase change structures.

12. The method according to claim 11, wherein the gap-fill protective layer is formed through a liquid phase coating process.

13. The method according to claim 11, wherein, after the step of forming the gap-fill protective layer, the method further comprises the step of densifying the gap-fill protective layer.

14. The method according to claim 13, wherein the step of densifying the gap-fill protective layer includes annealing the gap-fill protective layer at a temperature of 100° C. to 400° C. for 10 to 40 minutes.

15. The method according to claim 14, wherein the step of annealing activates the diffusion barrier ions in the protective layer.
